(19) United States
(12) Patent Application Publication
(10) Pub. No.: US 2002/0132489 A1
(43) Pub. Date: Sep. 19, 2002

(54) Method for fabricating a capacitor by using self-aligned etaching process

(75) Inventor: Ching-Yu Chang, Yuan-shan hsiang (TW)

Correspondence Address: LOWE HAUPTMAN GILMAN & BERNER, LLP, Suit 310, 1700 Diagonal Road, Alexanderia, VA, 22314, US

(73) Assignee: MACRONIX INTERNATIONAL CO., LTD.

(21) Appl. No.: 09/803,984

(22) Filed: Mar. 13, 2001

(51) Int. Cl. H01L 21/302; H01L 21/461

(52) U.S. Cl. 438/725

(57) ABSTRACT

A method for fabricating a capacitor by using self-aligned etching process is provided. First, a substrate has a plug structure thereon. An inter poly dielectric layer is deposited cover the substrate and plug structure. Next, a photoresist layer is formed on inter poly dielectric layer, wherein the photoresist layer has an opening pattern. Afterward, the inter poly dielectric layer overetch isotropically by using the photoresist layer as a mask to expose a portion of the plug structure such that the dielectric layer has a cup-like shape. The photoresist layer is then removed. A second conducting layer is deposited on the inter poly dielectric layer as a bottom electrode of the capacitor. Then, a dielectric layer is conformal deposited on the second conductive layer. Finally, a third conductive layer, again, is formed along the surface of dielectric layer as a top electrode of capacitor.

### BACKGROUND OF THE INVENTION

1. Field of the Invention

The present invention relates generally to a method for fabricating a capacitor, and more particularly to a method for fabricating a capacitor by using self-aligned etching process.

2. Description of the Prior Art

Capacitors are usually formed in an array of memory cell. The function of the capacitor is to store datum by charging or discharging. For example, binary bit datum is stored in the capacitor. The logic state of the binary bit datum is “0” when the capacitor discharges, while the logic state of the binary bit datum is “1” when the capacitor charges.

Usually, there is a dielectric layer formed between upper electrode of the capacitor and bottom electrode of the capacitor. The dielectric layer provides required dielectric constant.

As the performance of the microprocessor of the computer improves, there are demands for an increased amount of charge storage of capacitor and a higher quality memory cell. The methods of increasing the charge storage amount of the capacitor includes following: (1) increasing the surface area of the charge storage of the capacitor; (2) selecting a dielectric material with a high dielectric constant; and (3) decreasing the thickness of the dielectric layer between two electrodes of the capacitor. However, there are limitations on decreasing the thickness of the dielectric layer between two electrodes of the capacitor. Therefore, the better method of increasing the charge storage amount of the capacitor is to increase the surface area of the charge storage of the capacitor.

For conventional method to fabrication capacitor as shown in FIG. 1 to FIG. 3. With reference to FIG. 1, first dielectric layer 20 is formed on the substrate 10. Next, a photo mask region of photoresist layer 30 is formed on the surface of first dielectric layer 20 region except for a central region 40. Central region 40 is then etched, exposing structure 10 within central region 40 as shown in FIG. 2.

The photoresist layer 30 is then removed. Next, a first conductive layer 50 is deposited on the first dielectric layer 20 and filled in the opening 40 as a bottom electrode of capacitor. The first conductive layer 50 is deposited on the first dielectric layer 20 by performing an etching back process. Next, a second dielectric layer 60 and second conductivity layer 70 are formed on the first conducting layer 50 in sequence as an upper electrode of capacitor as shown in FIG. 3.

However, because the integration of integrated circuits (IC) is rising, the area that can be occupied by the capacitor decreases. The charge storage amount of the capacitor decreases, too. Therefore, a simple manufacturing method for a capacitor having a charge storage area with a large surface become one of the most important topics in current semiconductor research.

In accordance with the above description, a new and improved method for increasing capacitance by using self-aligned etching of capacitor is therefore necessary, so as to raise the yield and quality of the follow-up process.

### SUMMARY OF THE INVENTION

In accordance with the present invention, a method is provided for fabricating a capacitor by using self-aligned etching process that substantially overcomes drawbacks of above mentioned problems arise from the conventional methods.

Accordingly, it is a main object of the present invention to provide a method for fabricating a capacitor by using self-aligned etching process. This invention can form large surface area as a bottom electrode of capacitor.

Another object the present invention can increase the surface area of bottom electrode by changing the surface profile of the inter poly dielectric layer, wherein the surface shape is a cup-like shape.

Still another object of the present invention is to provide a method for fabricating a bottom electrode of the capacitor has large surface area. The present invention can increase bottom electrode surface area by self-aligned over etch method. Hence, the present invention can correspond to economic effect.

A method for fabricating a capacitor by using self-aligned etching process is provided. First, a substrate has a plug structure thereon. Next, an inter poly dielectric layer is deposited cover the substrate and the plug structure. Next, a photoresist layer is formed on the inter poly dielectric layer, wherein the photoresist layer has an opening pattern. Afterward, the inter poly dielectric layer over etch isotropically by using the photoresist layer as a mask to expose a portion of the plug structure such that the inter poly dielectric layer has a cuplike shape. The photoresist layer is then removed. A second conductive layer is deposited on the inter poly dielectric layer as a bottom electrode of the capacitor. Then, a dielectric layer is conformal deposited on the second conductive layer. Finally, a third conductive layer, again, is formed along the surface of dielectric layer as a top electrode of the capacitor.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIGS. 1 to 3 are showing a conventional method of fabricating capacitor.

FIGS. 4 is showing a plug structure on the substrate.

FIGS. 5 is followed FIG.4 showing a dielectric layer is deposited on the plug structure and substrate.

FIGS. 6 is followed FIG. 5 showing a photoresist layer formed on the dielectric layer, wherein the photoresist layer has an opening pattern.

FIGS. 7 is followed FIG. 6 showing the dielectric layer over etch such that the dielectric layer has a cup-like shape.

FIGS. 8 is followed FIG. 7 showing deposited a conductive layer, dielectric layer and conductive layer sequentially.

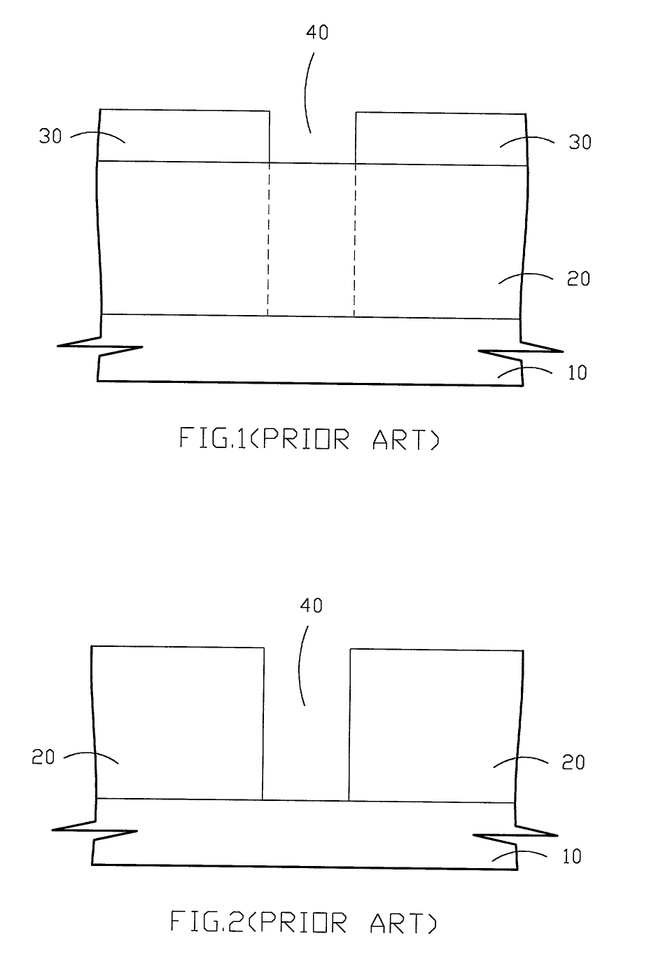

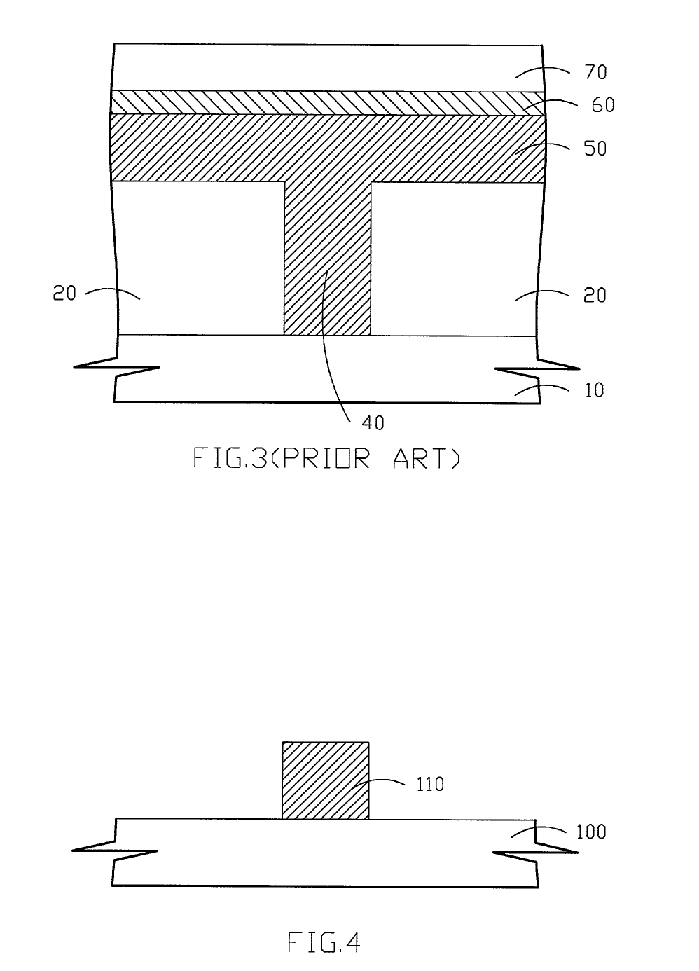

### DESCRIPTION OF THE PREFERRED EMBODIMENT

A preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

Reference will now be made in detail to a preferred embodiment of the invention, an example of which is illustrated in the accompanying drawings. FIGS. 4 to 8 illustrate a method for fabricating a capacitor by using self-aligned etching process in accordance with the present invention.

FIG. 4 shows a first step in the method for fabricating a capacitor by using self-aligned etching process. A first conductive layer is deposited to cover the substrate 100. In this embodiment, the first conductive layer is polysilicon. Then, a photoresist layer is formed on the first conductive layer. The exposure of the photoresist layer may utilize I-line or deep ultra-violet ray. Afterward, the first conductive layer is etched by dry etch process by using the photoresist layer as etch mask to form a plug structure 110 as show in FIG.4. The above etch process is an anisotropic etch process.

As shown in FIG. 5, for fabricating the capacitor by using self-aligned porcess, an inter poly dielectric layer 120 is then deposited on the substrate 100 and the plug structure 110. The inter poly dielectric layer 120 can be silicon oxide, silicon nitride, tetra-ethyl-ortho-silicate (TEOS) or borophosphosilicate glass (BPSG). In this embodiment, silicon oxide is preferred.

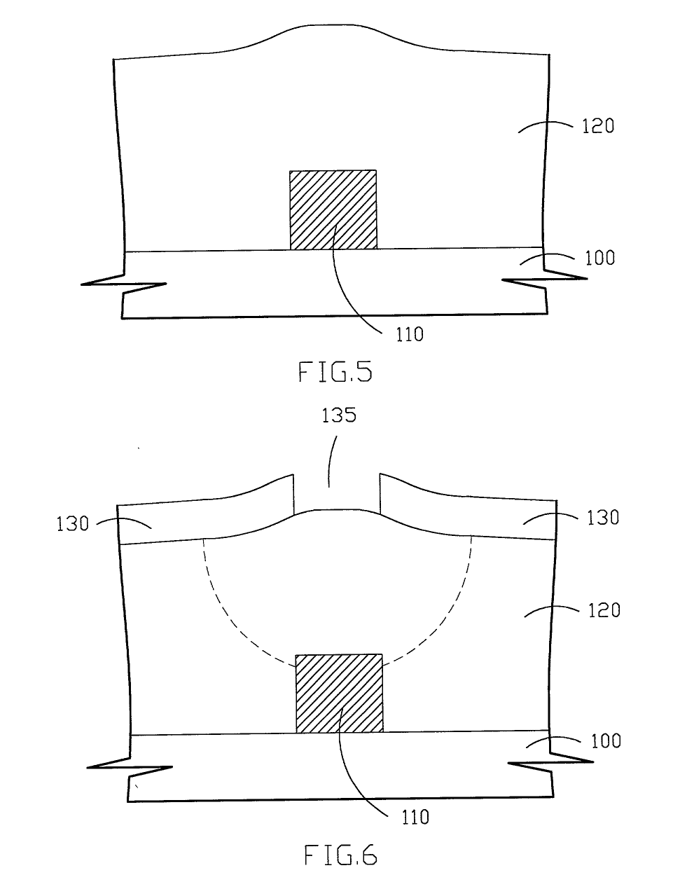

FIG. 6 shows a subsequent illustrative stage. A photoresist layer 130 is formed on the inter poly dielectric layer 120, wherein the photoresist layer 130 has an opening pattern 135. Afterward, inter poly dielectric layer 120 is etched by wet etch process by using the photoresist layer 130 as etch mask.

The above etch process is an isotropic etch process. The wet etching solution is a hydrofluoric acid (HF) or a buffered oxide etch (BOE) solution which consists of hydrofluoric acid (HF) with an amount of the additional ammonium fluorideO (NH4F) to buffer the strong etching property of hydrofluoric acid (HF). Furthermore, the buffered oxide etching speed may be adjusted by adding water to the hydrofluoric acid (HF).

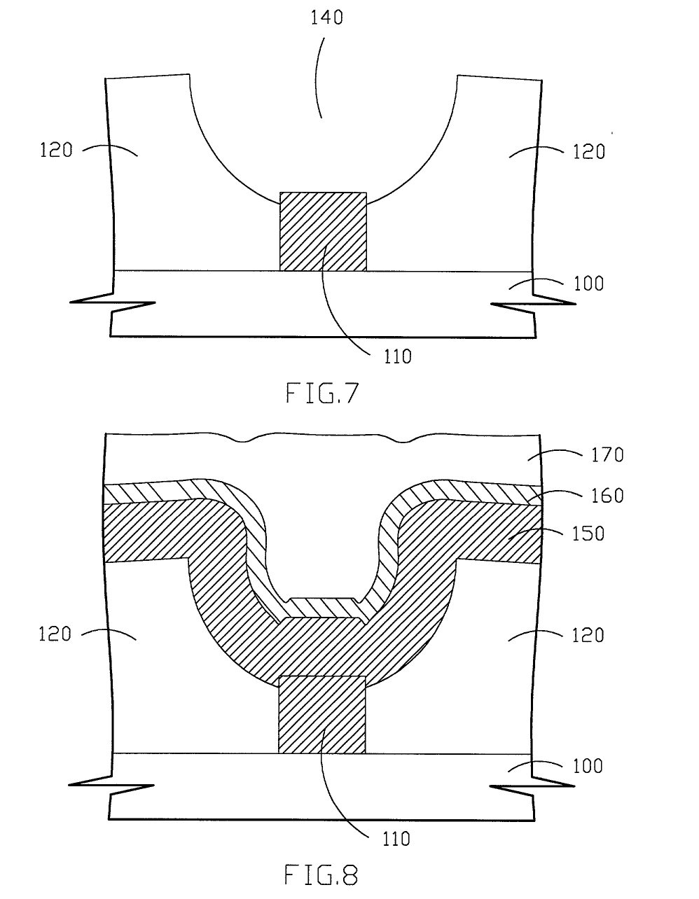

In order to achieve an improved capacitance by using selfaligned etching method. The inter poly dielectric layer 120 is overetch isotropic by using the photoresist layer 130 as a mask to expose a portion of the plug structure 110 such that the inter poly dielectric layer 120 has a cup-like shape 140. The photoresist layer 130 is then removed, as shown in FIG. 7.

As shown in FIG. 8 following the removed photoresist layer 130, a second conformal conductive layer 150 is deposited on the inter poly dielectric layer 120 as a bottom electrode of the capacitor. The material of conformal conductive layer 150 may be polysilicon.

Next step, a dielectric layer 160 is formed on the second conformal conductive layer 150. The dielectric layer 160 is preferably made silicon nitride layer sandwished by two silicon oxide layers (SiO/SiN/SiO; ONO), having a thickness between about 50 to about 300 angstrom.

Next step, the third conductive layer 170 is deposited on dielectric layer 160 as a top electrode of the capacitor. The material of third conductive layer 170 is polysilicon.

Applying this method can control dimension of device and fit in with special process, and we don't need add another dry etch step after wet etch step. Moreover, line width 110, 135 of substrate and photoresist layer can be controlled respectively to increase process window.

In this embodiment of the present invention, as discussed above, the surface area is increased by the cup-like structure, so as to increase the capacitance. Hence, the method of the present invention can correspond to economic effect, it is also able to reach to purpose that economize on cost.

Obviously, many modifications and variations of the present invention are possible in light of the above teachings. It is therefore to be understood that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for fabricating a bottom electrode of capacitor by using self-aligned etching process, said method comprising:
forming a first conductive layer on a substrate;
etching said first conductive layer to forming a plug structure on said substrate;
depositing a first dielectric layer on said plug structure;
forming a photoresist layer on said first dielectric layer, wherein said photoresist layer has an opening pattern;
overetching said first dielectric layer isotropically by using said photoresist layer as a mask to expose a portion of said plug structure such that said first dielectric layer has a cup-like shape;
removing said photoresist layer;
depositing a second conductive layer on said first dielectric layer.

2. The method according to claim 1, wherein material of first conductive layer is polysilicon.

3. The method according to claim 1, wherein said step of etching said first conductive layer is an anisotropic method.

4. The method according to claim 1, wherein said first dielectric layer is a material selected from the group consisting of silicon oxide, silicon niter, tetra-ethyl-ortho-silicate (TEOS), and borophosphosilicate glass (BPSG).

5. The method according to claim 1, wherein said step of over etching is isotropical selected from the group consisting of hydrofluoric (HF) and buffered oxide etch (BOE) solution.

6. The method according to claim 1, wherein material of said conformal second conductive layer is polysilicon.

7. A method for fabricating a capacitor by using self-aligned etching process, said method comprising:
forming a first conductive layer on a substrate;
etching said first conductive layer to forming a plug structure on said substrate;
depositing a first dielectric layer on said plug structure;
forming a photoresist layer on said first dielectric layer, wherein the phororesist layer has an opening pattern;
overetching said first dielectric layer isotropically by using said photoresist layer as a mask to expose a portion of said plug structure such that said first dielectric layer has a cup-like shape;
removing said photoresist layer;
depositing a second conductive layer on said first dielectric layer as a bottom electrode of said capacitor;
depositing a conformal second dielectric layer on said conformal second conductive layer; and
depositing a conformal third conductive layer on said conformal second dielectric layer as a top electrode of said capacitor.

8. The method according to claim 7, wherein material of said first conductive layer is polysilicon.

9. The method according to claim 7, wherein said step of etching said first conductive layer is an anisotropical method.

10. The method according to claim 7, wherein said first dielectric layer is a material selected from the group consisting of silicon oxide, silicon niter, tetra-ethyl-ortho-silicate (TEOS), and borophosphosilicate glass (BPSG).

11. The method according to claim 7, wherein said step of overetching is isotropic selected from the group consisting of hydrofluoric (HF) and buffered oxide etch (BOE) solution.

12. The method according to claim 7, wherein material of said conformal second conductive layer is polysilicon.

13. The method according to claim 7, wherein said material of conformal second dielectric layer is silicon nitride layer sandwished by two silicon oxide layers (ONO).

14. The method according to claim 7, wherein material of said third conductive layer is polysilicon.

15. A method for fabricating a capacitor by using self-aligned etching process, said method comprising:
forming a first polysilicon layer on a substrate;
etching said first polysilicon layer to forming a plug structure on said substrate;
depositing a inter poly dielectric layer on said plug structure;
forming a photoresist layer on said inter poly dielectric layer, wherein the phororesist layer has an opening pattern;
overetching said inter poly dielectric layer isotropically by using said photoresist layer as a mask to expose a portion of said plug structure such that said inter poly dielectric layer has a cup-like shape;
removing said photoresist layer;
depositing a second polysilicon layer on said inter poly dielectric layer as a bottom electrode of said capacitor;
depositing a dielectric layer on said conformal second polysilicon layer, wherein material of said dielectric layer comprises a silicon nitride layer sandwished by two silicon oxide layers; and
depositing a third polysilicon layer on said conformal dielectric layer as a top electrode of said capacitor.

16. The method according to claim 15, wherein said step of etching said first polysilicon layer is an anisotropic method.

17. The method according to claim 15, wherein said inter poly dielectric layer is a material selected from the group consisting of silicon oxide, silicon niter, tetra-ethyl-ortho-silicate (TEOS), and borophosphosilicate glass (BPSG).

18. The method according to claim 15, wherein said step of overetching is isotropical selected from the group consisting of hydrofluoric (HF) and buffered oxide etch (BOE) solution.
